(19) United States
(12) Patent Application Publication
(10) Pub. No.: US 2006/0198115 A1
(43) Pub. Date: Sep. 7, 2006

(54) Mounting apparatus for expansion card

(75) Inventors: Hsuan-Tsung Chen, Tu-Cheng (TW); Shao-Bo Han, Shenzhen (CN); Wei-Bin Hua, Shenzhen (CN)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry CO., LTD., Tu-Cheng City (TW)

(21) Appl. No.: 11/367,096

(22) Filed: Mar. 3, 2006

(30) Foreign Application Priority Data
Mar. 3, 2005 (CN) 200520055500.1

(51) Int. Cl. H05K 7/18

(52) U.S. Cl. 361/796; 361/801

(57) ABSTRACT

A mounting apparatus for expansion cards (50) each having an end plate (53) includes a wall (11) having a cage (111) arranged thereto; a catch member (116) arranged to the wall; and a retaining piece (30) movable with respect to the cage and cooperating with the cage for sandwiching the end plates of the expansion cards therebetween. One end of the retaining piece is disengageably engageable with the catch member for being attached to the wall.

### BACKGROUND OF THE INVENTION

1. Field of the Invention

The present invention relates to a mounting apparatus for electronic device, and more particularly to a mounting apparatus for expansion card.

2. General Background

Computer systems typically require or include expansion cards which extend the capabilities of computer systems by providing dedicated hardware to achieve a variety of tasks. Graphics adapters, high speed network controllers, hard disk controllers, sound cards, and modem cards are among some of the more common types of expansion cards, although those knowledgeable in the field of computer systems will recognize a wide variety of other types of expansion cards. Expansion cards are typically attached in the computer systems by screws. However, attachment with screws is unduly complicated and time consuming, particularly when several expansion cards are fixed. In addition, a tool is usually required for installation and removal of the screws.

To address aforesaid problems, a number of mounting apparatuses such as disclosed in U.S. Pat. Nos. 4,745,524, 5,317,483 and 5,936,835 is invented to minimize number of screws to be used.

What is desired, therefore, is a mounting apparatus which facilitates removal and attachment of expansion cards.

### SUMMARY

In one preferred embodiment, a mounting apparatus for an expansion card having an end plate includes a wall having a cage arranged thereto; a catch member arranged directly to the wall; and a retaining piece movable with respect to the cage and cooperating with the cage for sandwiching at least one portion of the end plate of the expansion card therebetween. One end of the retaining piece is disengageably engageable with the catch member.

Other advantages and novel features will become more apparent from the following detailed description of a preferred embodiment when taken in conjunction with the accompanying drawings, in which:

### BRIEF DESCRIPTION OF THE DRAWINGS

FIG. 1 is an exploded, isometric view of a mounting apparatus in accordance with a preferred embodiment of the present invention, and a plurality of expansion cards, the mounting apparatus including a retaining piece and an enclosure;

FIG. 2 is an enlarged view of the retaining piece of FIG. 1, but viewed from another aspect;

FIG. 3 is an assembled view of FIG. 1, showing the expansion cards are not fixed;

FIG. 4 is similar to FIG. 3, showing the expansion cards are fixed; and

FIG. 5 is similar to FIG. 4, but viewed from another aspect.

### DETAILED DESCRIPTION OF THE EMBODIMENT

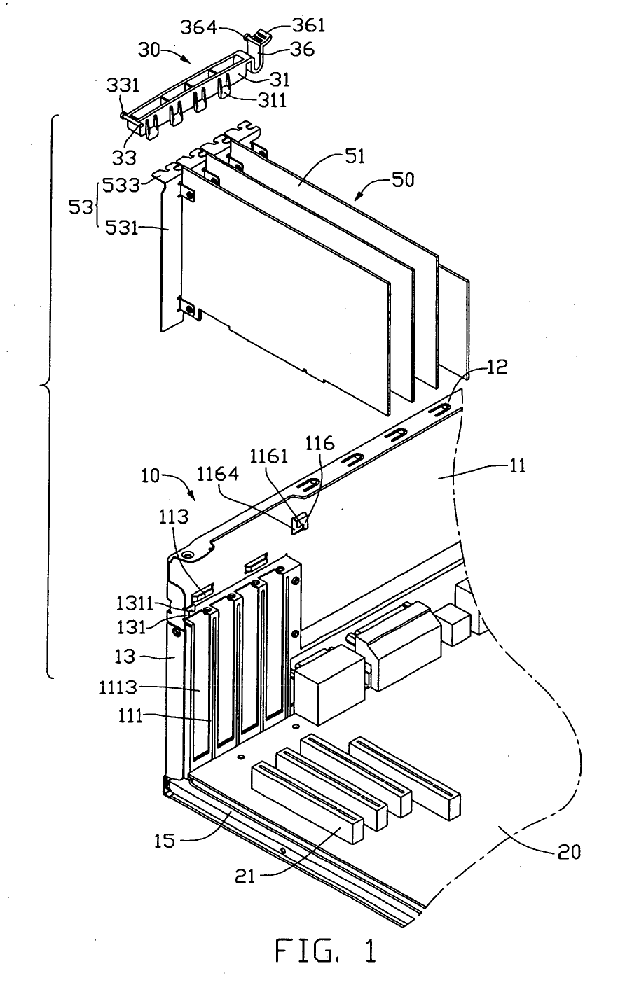

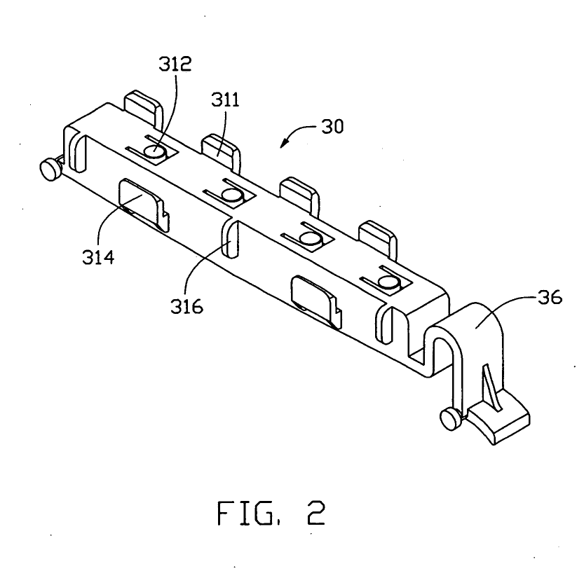

Referring to FIGS. 1 and 2, a mounting apparatus is provided to fix a plurality of expansion cards 50 in a computer, the mounting apparatus including an enclosure 10 and a retaining piece 30. Each expansion card 50 includes a printed circuit board (PCB) 51, and a generally L-shaped end plate 53 attached to an end of the PCB 51. The end plate 53 of each expansion card 50 includes an elongated body 531 and a bent portion 533 generally perpendicular to the body 531.

The enclosure 10 includes a first wall 11 and a second wall 15 arranged perpendicularly to a bottom edge of the first wall 11. A cage 111 is formed inwardly from the first wall 11 adjacent the second wall 15. A plurality of spaced apart vertical slots 1113 is defined in the cage 111, each slot 1113 being generally L-shaped in construction corresponding to the end plates 53 of the expansion cards 50. A pair of horizontal bridges 113 is punched inwardly from the first wall 11 over the cage 111. A catch member 116 is punched inwardly from the first wall 11, an opening 1164 is thereby defined in the first wall 11. A notch 1161 is cut into the catch member 116 from a bottom edge thereof. A horizontal first flange 12 is bent perpendicularly inwardly from a top edge of the first wall 11 and generally parallel to the second wall 15. A vertical second flange 13 is bent inwardly from a side edge of the first wall 11. A pair of parallel pedestals 131 is formed inwardly from the second flange 13, each pedestal 131 defining an indentation 1311 in a bottom edge thereof.

The second wall 15 supports a motherboard 20 thereon, and a plurality of connectors 21 is arranged on the motherboard 20 corresponding to the expansion cards 50.

The retaining piece 30 includes a body 31. A shaft 33 is formed on a first end of the body 31. Ahead portion 331 is formed at one end of the rod 33. A generally U-shaped elastic member 36 is integrally extended from a second end of the body 31. A handle 361 is formed from a free end of the elastic member 36. A short rod 364 ended at a head portion protrudes from a common edge of the handle 361 and the elastic member 36. A plurality of stopper members 311 extends downwardly from a first side surface of the body 31, corresponding to the end plates 53 of the expansion cards 50. Two hooks 314 are formed on a second side surface of the body 31 opposing the first side surface, corresponding to the bridges 113 of the enclosure 10. Three vertical tabs 316 are formed on the second side surface. A plurality of spring fingers 312 are formed in a bottom surface of the body 31, corresponding to the expansion cards 50.

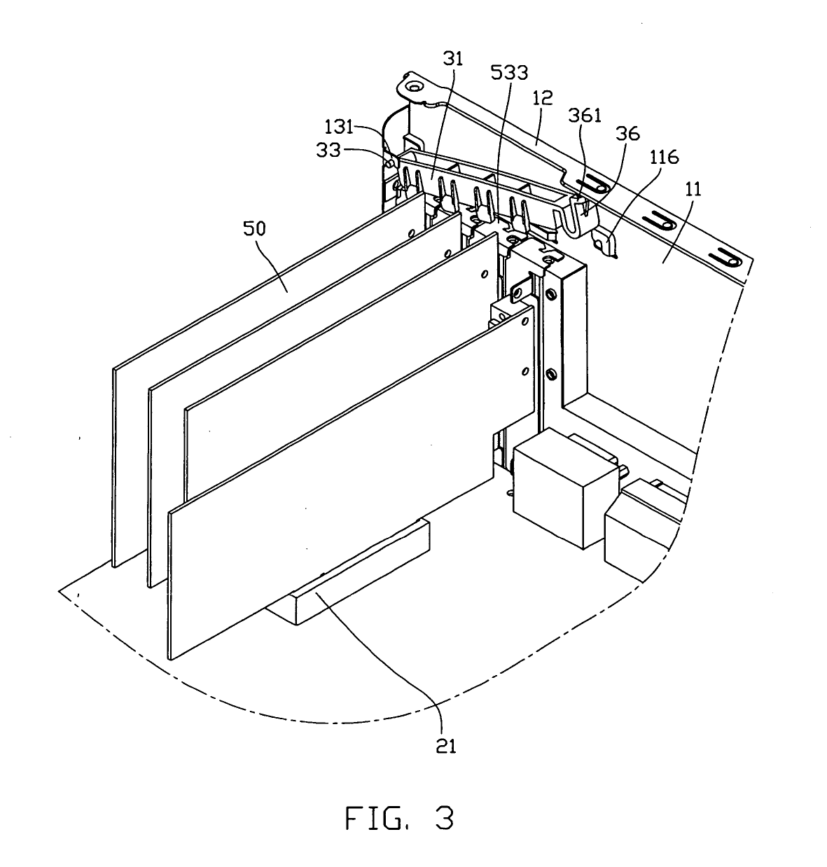

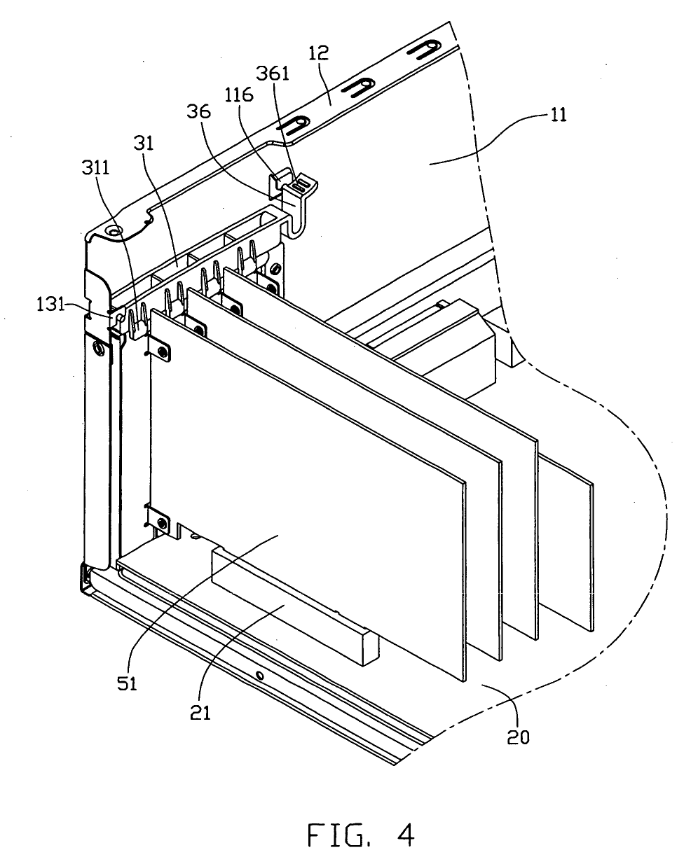

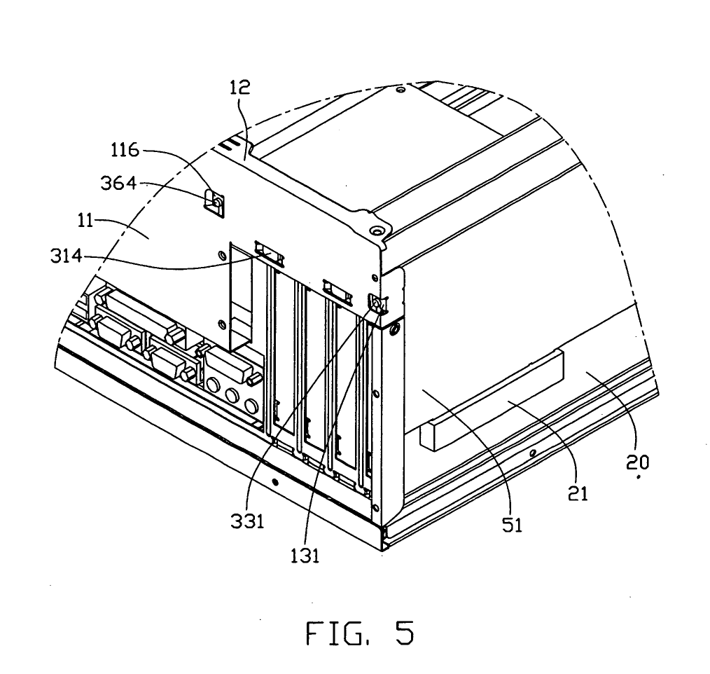

Referring to FIGS. 3 to 5, in assembly, the expansion cards 50 are plugged in the connectors 21 of the motherboard 20 respectively. The end plates 53 of the expansion cards 50 are positioned to the cage 111 of the first wall 11 in alignment with the slots 1113 of the cage 111 respectively. The bent portions 533 of the end plates 53 engage an upper side of cage 111. The first end of the body 31 of the retaining piece 30 is slantingly positioned below the pedestals 131. The shaft 33 of the retaining piece 30 pivotally engages in the indentations 1311 of the pedestals 131, with the head portion 331 of the shaft 33 located between the first wall 11 and the pedestal 131 neighboring the first wall 11. The handle 361 of the retaining piece 30 is positioned under the first flange 12 of the first wall 11, and the head portion of the rod 364 engages with the first wall 11.

In use, the retaining piece 30 is rotated toward the cage 111. The hooks 314 of the retaining piece 30 gradually enter corresponding bridges 113 of the first wall 11 in sequence. The head portion of the rod 364 enters the opening 1164 of the first wall 11. The rod 364 slides along a free side edge of the catch member 116, and the elastic member 36 is continuously compressed. When the rod 364 gets in a portion of the opening 1164 under the catch member 116, the elastic member 36 is restored to drive the rod 364 to finally engage in the notch 1161 of the catch member 116. The catch member 116 prevents reverse rotation of the retaining piece 30. The hooks 314 fully enter the corresponding bridges 113. The tabs 316 abut against the first wall 11, for helping securing the retaining piece 30 to the first wall 11. The spring fingers 312 of the retaining piece 30 engage the bent portions 533 of the end plates 53 respectively. The stopper members 311 engage the elongated bodies 531 of the end plates 53 respectively. The expansion cards 50 are thus firmly retained in the enclosure 10.

To detach the expansion cards 50, the handle 361 is pressed downwardly to disengage the retaining piece 30 from the catch member 116. The retaining piece 30 is reversely rotated to disengage from the end plates 53 of the expansion cards 50. The expansion cards 50 are ready to be removed from the enclosure 10.

It is believed that the present embodiment and its advantages will be understood from the foregoing description, and it will be apparent that various changes may be made thereto without departing from the spirit and scope of the invention or sacrificing all of its material advantages, the example hereinbefore described merely being a preferred or exemplary embodiment.

What is claimed is:

1. A mounting apparatus for an expansion card having an end plate, the mounting apparatus comprising:
a wall having a cage arranged thereto;
a catch member arranged directly to the wall; and
a retaining piece movable with respect to the cage and cooperating with the cage for sandwiching at least one portion of the end plate of the expansion card therebetween, one end of the retaining piece disengageably engageable with the catch member.

2. The mounting apparatus as claimed in claim 1, wherein a flange is formed to the wall, another end of the retaining piece pivotally connects to the flange.

3. The mounting apparatus as claimed in claim 2, wherein a pair of pedestals is arranged to the flange generally above the cage, the pedestals defines a pair of indentations respectively, and a shaft is arranged to said another end of the retaining piece and engaged in the indentations.

4. The mounting apparatus as claimed in claim 3, wherein the shaft ends at a head portion located between the wall and the pedestal adjacent the wall.

5. The mounting apparatus as claimed in claim 1, wherein said one end of the retaining piece comprises an elastic member, a rod is arranged to the elastic member, and a notch is defined in the catch member to engage with the rod for holding the retaining piece to the wall.

6. The mounting apparatus as claimed in claim 5, wherein the rod terminates at a head portion movable between the catch member and the wall and is dimensioned not to exist from the notch of the catch member.

7. The mounting apparatus as claimed in claim 5, wherein the elastic member is generally U-shaped.

8. The mounting apparatus as claimed in claim 1, wherein a bridge is formed on the wall, and a hook is formed on a side of the retaining piece engaging in the bridge for holding the retaining piece to the wall.

9. The mounting apparatus as claimed in claim 1, wherein a stopper member is formed downwardly from the retaining piece for preventing the end plate of the expansion card from disengaging from the cage.

10. A mounting apparatus for an expansion card having an end plate, the mounting apparatus comprising:
a planar wall having a cage arranged thereto, the cage adapted for engaging with the end plate of the expansion card;
a catch member formed from the planar wall; and
a retaining piece movable with respect to the cage and attached to the wall by means of engaging with the catch member, an engaging member arranged to the retaining piece for preventing the end plate from disengaging from the cage.

11. The mounting apparatus as claimed in claim 10, wherein the engaging member comprises a spring finger formed on a bottom surface of the retaining piece in cooperation with a top surface of the cage for sandwiching a portion of the end plate therebetween.

12. The mounting apparatus as claimed in claim 10, wherein the engaging member comprises a stopper member depending from the retaining piece in cooperation with a side surface of the cage for sandwiching a portion of the end plate therebetween.

13. The mounting apparatus as claimed in claim 10, wherein a flange is bent from the wall, a pair of pedestals is arranged to the flange generally over the cage, the pedestals defines a pair of indentations respectively, and a shaft is arranged to the retaining piece and pivotally engaged in the indentations.

14. The mounting apparatus as claimed in claim 10, wherein one end of the retaining piece comprises an elastic member, a rod is arranged to the elastic member, and a notch is defined in the catch member to engage with the rod for holding the retaining piece to the wall.

15. An electronic device comprising:
a first wall of the electronic device having a card cage arranged outwardly therefrom;
a second wall of the electronic device supporting a motherboard thereon, a card having an end plate and connected to the motherboard, the end plate supported on the card cage; and
a retaining piece having a pivotal end and an elastic end, a protruding member formed from the elastic end toward the first wall, the retaining piece rotatable with respective to the card cage between a first position where the card is ready to be disconnected from the motherboard and a second position where at least one portion of the end plate of the card is firmly attached between the retaining piece and the card cage, the protruding member engaging with the first wall to secure the retaining piece to the first wall at the second position.

16. The electronic device as claimed in claim 15, wherein a catch member is arranged directly to the first wall, a notch is defined in the catch member, the protruding member of the retaining piece is shaped as a rod terminating at a head portion to engage in the notch of the catch member.

17. The electronic device as claimed in claim 15, wherein a flange is bent from the first wall, a pair of pedestals is arranged to the flange, the pedestals defines a pair of indentations respectively, and the pivotal end of the retaining piece comprises a shaft pivotally engaged in the indentations.
